(19) United States
(12) Patent Application Publication
(10) Pub. No.: US 2010/0022098 A1
(43) Pub. Date: Jan. 28, 2010

(54) METHOD FOR MANUFACTURING SEMICONDUCTOR DEVICE

(76) Inventors: Kentaro MATSUNAGA, Kanagawa-ken (JP); Shinichi ITO, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/503,599

(22) Filed: Jul. 15, 2009

(30) Foreign Application Priority Data
Jul. 23, 2008 (JP) 2008-189483

(51) Int. Cl. H01L 21/31

(52) U.S. Cl. 438/758; 257/E21.24

(57) ABSTRACT

A method for manufacturing a semiconductor device includes: performing modifying a surface of a semiconductor wafer including a silanol group on the surface with an alkylsilyl group; and fluorinating an alkyl group of the alkylsilyl group with which the surface was modified.

### CROSS-REFERENCE TO RELATED APPLICATIONS

This application is based upon and claims the benefits of priority from the prior Japanese Patent Application No. 2008-189483, filed on Jul. 23, 2008; the entire contents of which are incorporated herein by reference.

### BACKGROUND OF THE INVENTION

1. Field of the Invention

The present invention relates to a method for manufacturing a semiconductor device including a step that forms a mask on a film to be fashioned and patterns the film.

2. Background Art

Generally, it is necessary to improve the exposure wavelength and/or the numerical aperture (NA) of lithography to advance the miniaturization of semiconductor integrated circuits. Immersion exposure is one technology that improves the numerical aperture. Technology discussed in, for example, JP-A 2004-93832 (Kokai) forms a mask material in two stages and thereby obtains an opening pattern having a finer width or diameter. Although such technologies facilitate miniaturization of patterns, the technologies are susceptible to various problems.

### SUMMARY OF THE INVENTION

According to an aspect of the invention, there is provided a method for manufacturing a semiconductor device, including: performing modifying a surface of a semiconductor wafer including a silanol group on the surface with an alkylsilyl group; and fluorinating an alkyl group of the alkylsilyl group with which the surface was modified.

According to another aspect of the invention, there is provided a method for manufacturing a semiconductor device including performing hydrophobizing on an exposed hydrophilic first surface of a semiconductor wafer including, on the same major surface side, the first surface and a hydrophobic second surface patterned on the first surface to expose a portion of the first surface.

According to another aspect of the invention, there is provided a method for manufacturing a semiconductor device, including: forming a first mask which can supply an acid and includes an opening pattern on a semiconductor substrate; performing hydrophobizing on an exposed surface of the first mask; forming a second mask which is crosslinkable by acid on the first mask in a way that causes the second mask to enter partway into the opening; causing a crosslinking reaction of a portion of the second mask contacting the first mask by supplying acid from the first mask to the second mask by baking; and performing developing to remove a portion of the second mask that is not crosslinked.

### BRIEF DESCRIPTION OF THE DRAWINGS

FIGS. 1A to 1C are schematic views illustrating main component steps of a method for manufacturing a semiconductor device according to a first embodiment of the present invention;

FIGS. 2A and 2B are schematic views illustrating a comparative example compared to a method for manufacturing a semiconductor device according to a second embodiment of the present invention;

FIGS. 3A to 3C are schematic views illustrating main component steps of a method for manufacturing a semiconductor device according to the second embodiment of the present invention;

FIGS. 4A to 4D are schematic views illustrating main component steps of a method for manufacturing a semiconductor device according to a third embodiment of the present invention;

FIGS. 5A and 5D are schematic views illustrating a comparative example compared to a method for manufacturing a semiconductor device according to the third embodiment of the present invention; and

FIGS. 6A to 6D are schematic views to illustrate problems in the comparative example shown in FIGS. 5A to 5D.

### DETAILED DESCRIPTION OF THE INVENTION

Immersion exposure is a technology that achieves miniaturization of a pattern using a large-diameter optical system by filling the space between the projection lens and the semiconductor wafer with, for example, purified water having a refractive index higher than that of air. In such immersion lithography, a protective film (top coat) may be formed between the semiconductor wafer and the purified water to prevent contact between the semiconductor wafer and the purified water and problems that occur thereby (such as penetration of the purified water into the resist, elution of resist components into the purified water, etc.).

Because exposure is performed by scanning, it is necessary that the protective film is highly hydrophobic (water-repellent) so that the purified water moves smoothly over the wafer. However, in the case where such a protective film is formed on, for example, an oxide film formed on a silicon substrate surface, the oxide film includes a silanol group (OH bonded to Si), is hydrophilic, and therefore cannot adhere well to the protective film which is hydrophobic. Generally, “hydrophilic” refers to the case where the contact angle is 40 degrees or less, and “hydrophobic” refers to the case where the contact angle is greater than 40 degrees.

A poor adhesion with the protective film may cause the protective film to separate as particles and undesirably contaminate the exposure apparatus. Such contamination of the exposure apparatus may lead to the exposure apparatus being stopped, which reduces productivity.

One method to make a surface hydrophobic is to fluorinate the surface to be processed. According to this method, it is possible to achieve a contact angle with the surface greater than 70 degrees for an organic film including, for example, C (carbon). However, the surface of the substrate to be fashioned which includes a silanol group unfortunately cannot undergo direct fluorination.

One hydrophobic treatment for a surface including a silanol group is a method that exposes the surface to, for example, an HMDS (Hexamethyldisilazane) vapor atmosphere. By this method, it is possible to bond an alkylsilyl group to the Si—O of the surface and increase the contact angle. Although a water drop on a silicon oxide film without silylation has a contact angle of a few degrees, the treatment recited above can increase the contact angle to about 65 degrees. However, such a method can increase the contact angle only to about 65 degrees and is insufficient to provide a high adhesion with, for example, a hydrophobic protective film such as that described above.

Therefore, in the embodiments of the present invention, a semiconductor wafer surface is made hydrophobic by treatment that modifies a semiconductor wafer surface including a silanol group with an alkylsilyl group and then fluorinates an alkyl group of the alkylsilyl group with which the surface was modified. Here, the semiconductor wafer surface to be processed includes the surface of the semiconductor substrate itself, surfaces of natural oxide films of the semiconductor substrate surface, and surfaces of films intentionally formed on the semiconductor substrate.

### First Embodiment

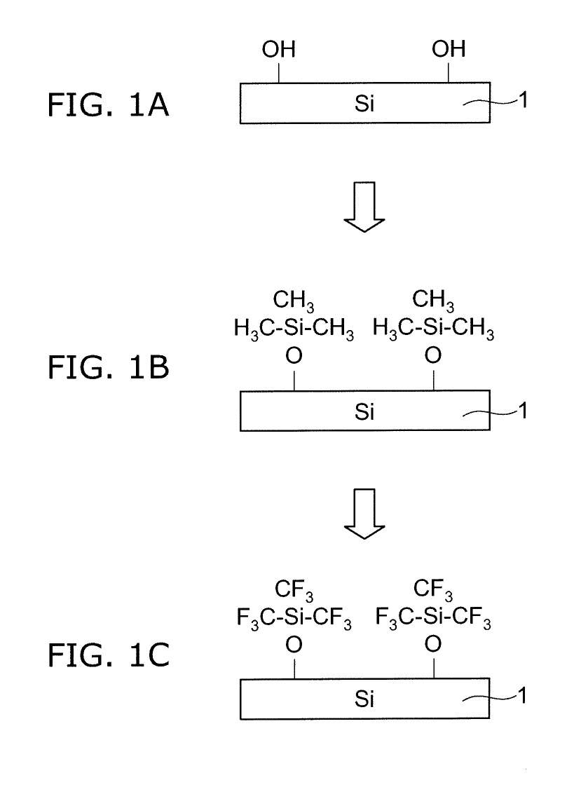

FIGS. 1A to 1C are schematic views illustrating main component steps of a method for manufacturing a semiconductor device according to a first embodiment of the present invention.

FIG. 1A is a schematic cross-sectional view of a silicon substrate 1 including a silicon oxide film, namely, a silanol group on the surface thereof. A vapor of, for example, HMDS (Hexamethyldisilazane) was introduced as an alkylsilylating agent into a chamber in which the silicon substrate 1 was placed; and the surface of the silicon substrate 1 was exposed to the vapor. Treatment was performed in this state with a chamber temperature of 100° C. for 90 seconds.

Thereby, the silicon oxide of the surface of the silicon substrate 1 is modified with an alkylsilyl group (in this embodiment, for example, a trimethylsilyl group) as illustrated in FIG. 1B.

Then, the silicon substrate 1 was placed in a chamber for fluorination. A vacuum was pulled on the chamber to remove oxygen, after which fluorine gas was introduced. The surface modified with the alkylsilyl group was exposed to the fluorine gas for 180 seconds. Thereby, an alkyl group (CH₃ in the example of FIG. 1B) is fluorinated and changed to CF₃ (a C—H group changes to a C—F group) as illustrated in FIG. 1C.

As a result, a contact angle of the surface of the silicon substrate 1 of at least 100 degrees was able to be obtained. The obtained contact angle is controllable by adjusting the concentration of the fluorine gas, reaction time, chamber pressure, etc.

According to this embodiment, a hydrophobic (water-repellent) surface having a large contact angle greater than about 65 degrees can be obtained even for a surface including a silanol group which cannot undergo direct fluorination by performing the two-stage hydrophobizing treatment described above.

After making the surface hydrophobic, a hydrophobic material such as the protective film described above is formed on the surface of the silicon substrate 1 by application in a liquid state. In this embodiment, a hydrophobic film is formed on a hydrophobic surface. Therefore, the adhesion of the film can be increased and film separation can be suppressed. As a result, contamination of the exposure apparatus and process discrepancies can be prevented, and productivity can be increased.

### Second Embodiment

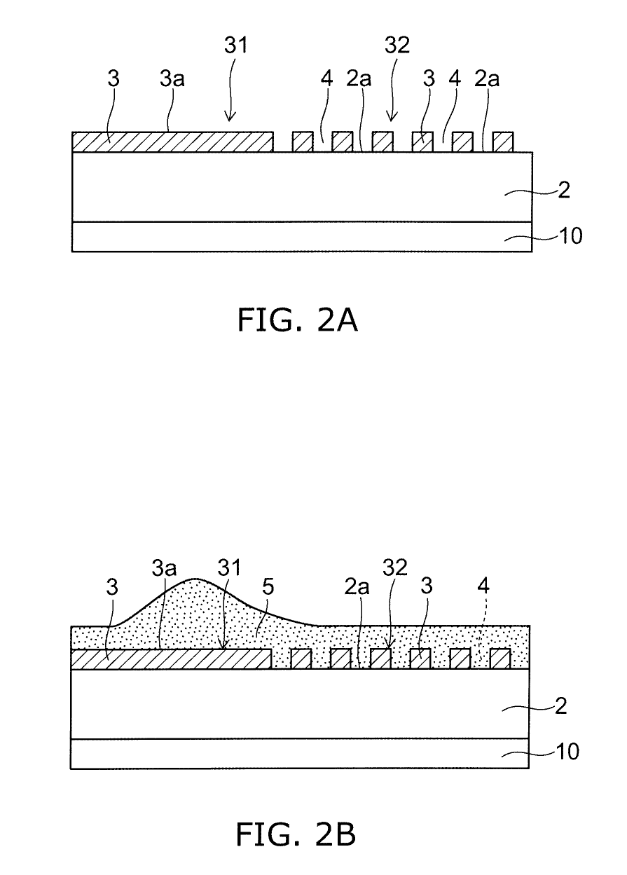

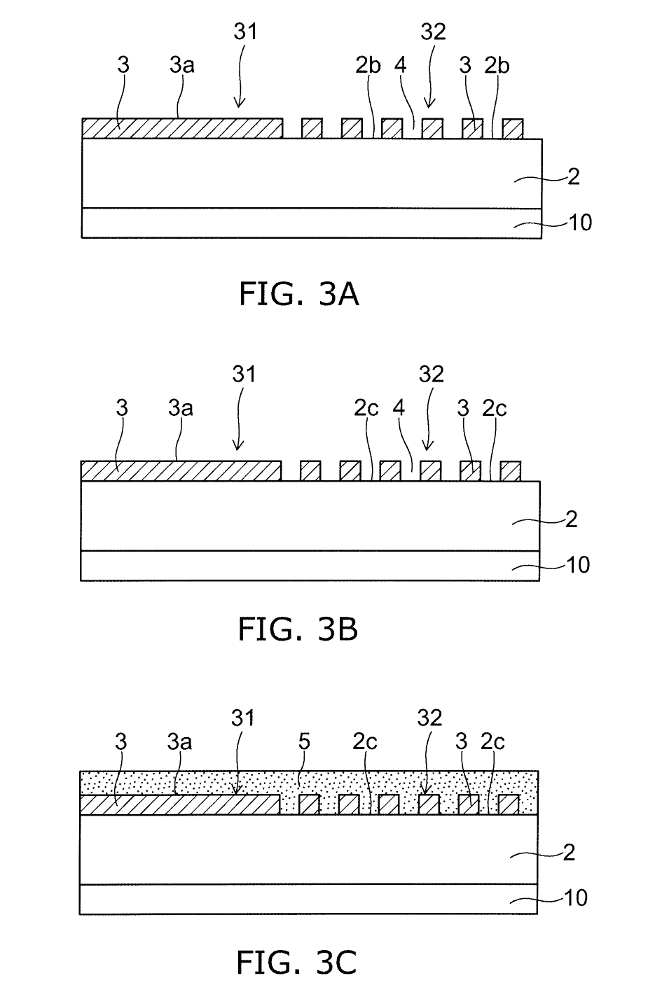

A second embodiment of the present invention will now be described with reference to FIGS. 2A to 3C.

FIG. 2A is a schematic cross-sectional view of a semiconductor wafer in which a silicon oxide film 2 (SiO₂) and a silicon nitride film 3 (SiN) are formed in order on a silicon substrate 10.

Patterning is performed on the silicon nitride film 3 to make openings 4 in a portion thereof. The layer therebelow, i.e., the surface of the silicon oxide film 2, is exposed at the bottom of each opening 4. The silicon nitride film 3 includes a first portion 31 in which the silicon nitride film 3 is spread thereover without openings 4 made therein; and a second portion 32 in which the openings 4 are densely made and the surface of the silicon oxide film 2 is exposed.

A surface 3a of the first portion 31 is silicon nitride and does not include O (oxygen). Therefore, the surface 3a is hydrophobic and has a contact angle θA of about 70 degrees. A surface 2a of the silicon oxide film 2 exposed at the second portion 32 includes O (oxygen) and is hydrophilic. A contact angle θB of the surface 2a is about 30 degrees. Accordingly, the semiconductor wafer has a structure in which a hydrophobic surface and a hydrophilic surface coexist on the same major surface side.

The case is considered where a film formation material in a state having fluidic properties is supplied to form a coating film on the semiconductor wafer surface. At this time, the apparent contact angle of the wafer surface differs greatly for the first portion 31 and the second portion 32 due to the contact angles of the surfaces and the multi-level configuration of the wafer surface. Therefore, the coating material coalesces between the first portion 31 and the second portion 32. Specifically, the coating material coalesces from the first portion 31 having a large contact angle to the second portion 32 having a small contact angle; and as illustrated in FIG. 2B, the coating film material in the portion having a large contact angle coalesces and stabilizes; a coating film 5 locally swells upward; and the planarity is undesirably poor.

The coating film was observed to swell upward about 50 μm in the thickness direction in a region of about 20 μm proximal to the boundary between the first portion 31 and the second portion 32 in the case where the silicon oxide film 2 was formed with a thickness of 250 nm, the silicon nitride film 3 was formed with a thickness of 60 nm, and the coating film material was supplied to the wafer surface to form a film thickness of 100 μm. A poor planarity of the coating film 5 causes process discrepancies in subsequent steps.

Therefore, in this embodiment, a vapor of, for example, HMDS was introduced as an alkylsilylating agent into the chamber in which the semiconductor wafer illustrated in FIG. 2A was placed to expose the surfaces of the first portion 31 and the second portion 32 to the HMDS vapor. Treatment was performed in this state with a chamber temperature of 100° C. for 90 seconds.

Thereby, the surface of the silicon oxide film 2 of the second portion 32 is modified with an alkylsilyl group (in this embodiment, for example, a trimethylsilyl group). A surface 2b of the silicon oxide film 2 modified with the alkylsilyl group is illustrated in FIG. 3A. The surface 3a of the first portion 31 is silicon nitride and does not include O (oxygen), and therefore is not modified with the alkylsilyl group by the HMDS treatment recited above.

Then, the wafer was placed in a chamber for fluorination. A vacuum was pulled on the chamber to remove oxygen, after which fluorine gas was introduced. The surface 2b modified with the alkylsilyl group was exposed to the fluorine gas for 180 seconds. Thereby, an alkyl group is fluorinated; and a structure is obtained in which a fluorinated surface 2c is exposed at the bottom of each opening 4 of the second portion 32 as illustrated in FIG. 3B.

At this time, the surface 3a of the first portion 31 does not include CHx (hydro carbon) and therefore is not fluorinated even when exposed to fluorine gas. Accordingly, the surface 3a of the first portion 31 remains unchanged as a hydrophobic silicon nitride even after undergoing the HMDS treatment and the fluorination recited above.

Conversely, the surface of the silicon oxide film 2 of the second portion 32 changes from hydrophilic to hydrophobic by the HMDS treatment and the fluorination recited above. As a result, the contact angles of the first surface 3a and the second surface 2c can be provided to be substantially the same or have a small difference therebetween; and the flow of the coating film material on the first surface 3a and the second surface 2c can be suppressed when the coating film material is supplied thereto. As a result, the coating film is prevented from locally swelling upward, and the film thickness uniformity (planarity) improves. The contact angle of the second surface 2c is controllable by adjusting the concentration of the fluorine gas, reaction time, chamber pressure, etc.

After the step illustrated in FIG. 3B, a hydrophobic coating film material having fluidic properties was supplied on the entire wafer surface. As illustrated in FIG. 3C, the coating film 5 was able to be formed with a uniform film thickness of, for example, 100 μm without local film thickness variation (swelling upward).

In this embodiment as well, a hydrophobic film is formed on a hydrophobic surface. Therefore, the adhesion of the film can be increased and film separation can be suppressed. As a result, contamination of the exposure apparatus and process discrepancies due to film separation can be prevented, and productivity can be increased.

The surface exposed at the bottom of the opening 4 of the second portion 32 may be made hydrophobic by direct fluorination without performing silylation with the alkylsilylating agent in the case where the exposed surface material includes CHx (hydro carbon) and can undergo direct fluorination.

In addition to HMDS, the alkylsilylating agent used when modifying the surface with the alkylsilyl group may include TMSDEA (Trimethylsilyldiethylamine), DMSDEA (Dimethylsilyldiethylamine), TMSDMA (Trimethylsilyldimethylamine), DMSDMA (Dimethylsilyldimethylamine), and the like.

The film formed on the surface that is made hydrophobic in the first embodiment and the second embodiment is not limited to a protective film for immersion exposure. It is sufficient that the film is hydrophobic, and may be, for example, an antireflective film, resist, etc.

### COMPARATIVE EXAMPLE

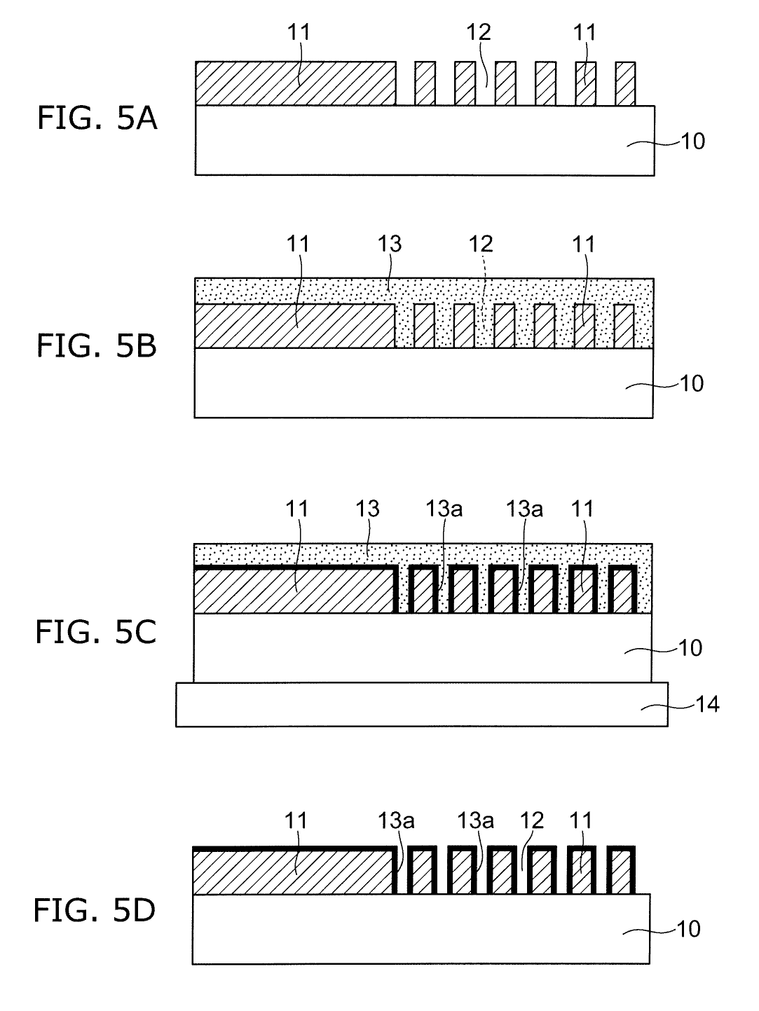

FIGS. 5A to 5D illustrate a method of lithography in a step for patterning a semiconductor integrated circuit that forms a groove pattern having a width at or below the resolution limit of the exposure wavelength and/or a hole pattern having a diameter at or below the resolution limit.

FIG. 5A is a schematic cross-sectional view of a structure in which a first mask 11 is formed on a film to be fashioned 10 (a silicon substrate, silicon oxide film, silicon nitride film, or the like).

Openings 12 are made in the first mask 11 in a groove or hole configuration. The first mask 11 is formed by a material which can supply acid to a second mask described below, and is, for example, a chemical amplification resist which produces acid when heated.

After patterning to make the openings 12 in the first mask 11, a second mask 13 is formed to cover the first mask 11 as illustrated in FIG. 5B. The second mask 13 is formed by a material including a water-soluble resin component crosslinkable by acid, water, and a water-soluable organic solvent. The second mask 13 is applied onto the first mask 11 in a liquid state having fluidic properties.

Then, as illustrated in FIG. 5C, baking is performed to heat the wafer from the underside using a heat plate 14. Acid is produced in the first mask 11 and the diffusion of the acid is facilitated. Thereby, portions of the second mask 13 contacting the first mask 11 (including portions contacting the interior faces of the openings 12) are crosslinked by the acid. The crosslinked portion 13a is insoluble in a developer such as water, alkaline, and the like.

Accordingly, the developer is used to remove the second mask 13 excluding the crosslinked portion 13a by developing as illustrated in FIG. 5D. By leaving the crosslinked resin portion 13a on the side faces inside each opening 12, an opening 12 can be obtained having a width or diameter smaller than the width or diameter of the opening 12 made by only patterning the first mask 11. By etching the film to be fashioned 10 using such a mask, it is possible to form a finer pattern.

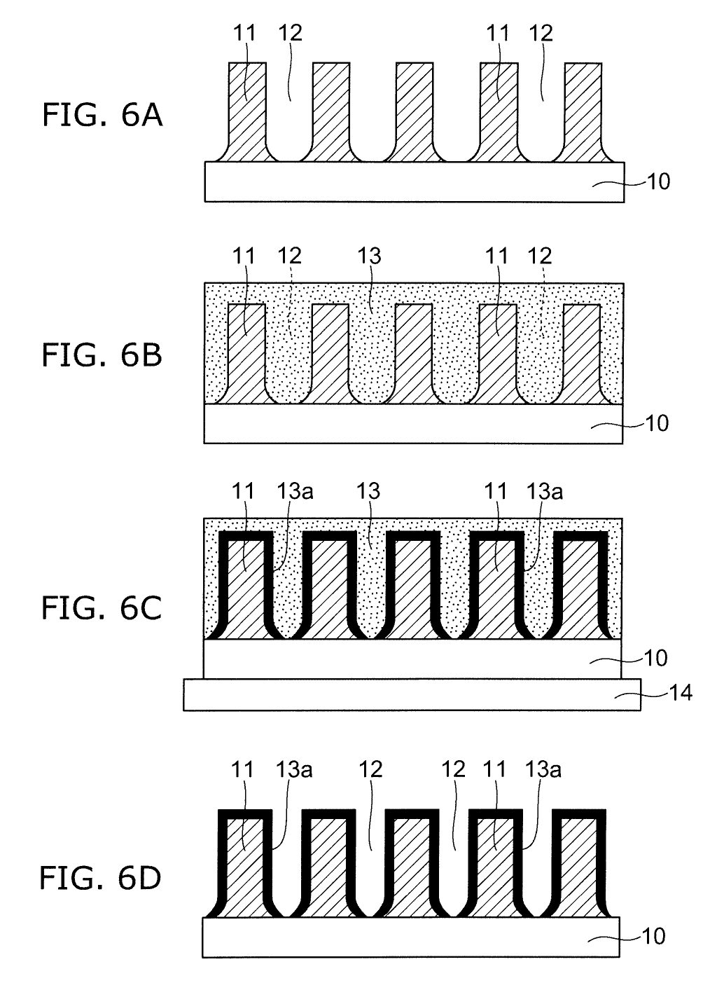

FIG. 6A is an enlarged schematic view of the portion in which the openings 12 are made.

FIG. 6A illustrates an example of a state during the patterning to make the openings 12 in the first mask 11 in which the width or diameter at the bottom side of each opening 12 is small and portions of the first mask 11 remaining on either side of each opening 12 are flared inward. Such a case occurs when the optical contrast of the exposure light is insufficient.

In such a case, the second mask 13 is applied as illustrated in FIG. 6B. Then, baking is performed as illustrated in FIG. 6C, and the crosslinked resin portions 13a formed on the side faces of the portions of the first mask 11 that flare inward then connect along the bottom face of the opening or have a small spacing therebetween. In such a case, as illustrated in FIG. 6D, the film to be fashioned 10 is not exposed at the opening 12 bottom, or the exposed surface area is small, which causes unopened defects to undesirably occur for the film to be fashioned 10, and/or transfer defects of the mask pattern to undesirably occur.

Although it may be considered to solve these problems by countermeasures for the crosslinked portion 13a undesirably formed at the bottom of the opening such as processing to remove by sputter etching, increasing the etching times during the etching of the film to be fashioned 10, etc., such additional processing leads to reduced film thickness of the mask material and reduced etching resistance of the mask material. As a result, configuration-fashioning defects of the film to be fashioned 10 may occur, or it may be impossible even to fashion the film to be fashioned 10.

### Third Embodiment

Therefore, in a third embodiment of the present invention, hydrophobizing treatment is performed on the first mask 11 prior to forming the second mask 13 on the first mask 11.

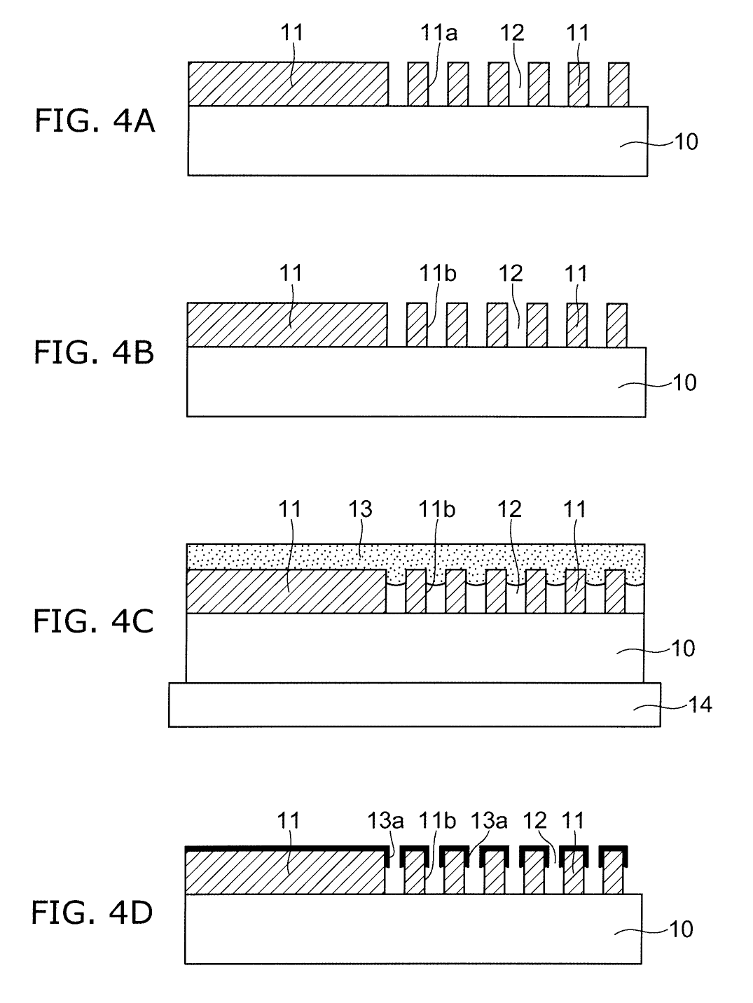

FIG. 4A is a schematic cross-sectional view of a structure in which the first mask 11 is formed on the film to be fashioned 10.

Openings 12 are made in the first mask 11 in a groove or hole configuration. The first mask 11 is formed by a material which can supply acid to the second mask 13, and is, for example, a chemical amplification resist which produces acid when heated.

Specifics of the patterning step of the first mask 11 will now be described. First, a silicon oxide film having a film thickness of 100 nm was formed as the film to be fashioned 10 on the uppermost layer of a wafer. An antireflective film material which prevents reflections of the exposure light was dropped onto the silicon oxide film and spin-coated using a spinner. Then, sintering was performed at 190° C. for 60 seconds. Then, the wafer temperature was returned to room temperature by cooling on a cooling plate for 60 seconds. The film thickness of the antireflective film after sintering was 77 nm.

Continuing, a resist for ArF exposure was dropped onto the antireflective film and spin-coated using a spinner. Then, sintering was performed at 120° C. for 60 seconds. The wafer temperature was then returned to room temperature by cooling on a cooling plate for 60 seconds. The film thickness of the resist film after sintering was 200 nm.

Then, a protective film for immersion exposure was dropped onto the resist film and spin-coated using a spinner. Sintering was then performed at 90° C. for 60 seconds. The wafer temperature was returned to room temperature by cooling on a cooling plate for 60 seconds. The film thickness of the protective film after sintering was 90 nm.

Continuing, the resist film was exposed using an ArF immersion exposure apparatus with a reduction projection. After exposure, baking was performed at 120° C. for 60 seconds, after which cooling was performed for 60 seconds on a cooling plate. Then, the wafer was immersed for 30 seconds in an alkaline developer of a 2.38% by weight TMAH (Tetramethylammonium hydroxide) aqueous solution, followed by rinsing with purified water. Thereby, the first mask 11 was formed with a hole pattern of openings 12 having diameters of 90 nm. The contact angle between the first mask 11 surface and water was 65 degrees.

Then, the wafer was placed in a chamber for fluorination. A vacuum was pulled on the chamber to exhaust oxygen, after which fluorine gas was introduced. The wafer was exposed to the fluorine gas for 180 seconds. By this treatment, a C—H group of the exposed surface (including an exposed surface 11a inside the opening 12) of the first mask 11 was changed (fluorinated) to a C—F group. Thereby, the exposed surface of the first mask 11 was able to be changed to a hydrophobic surface having a contact angle of about 90 degrees. A hydrophobic surface 11b (FIG. 4B) of the first mask 11 is formed by the fluorination of the exposed surface inside the opening 12.

Continuing, a material which forms the second mask material 13 was dropped onto the first mask 11 and spin-coated using a spinner. As illustrated in FIG. 4C, the second mask 13 covered the entire first mask 11.

At this time, the surface 11b exposed at the side face of the opening 12 is hydrophobic due to the fluorination recited above. Therefore, the so-called wettability of the surface 11b is poor, and the second mask material 13 can be inhibited from entering into the opening 12. In other words, the second mask material 13 does not reach the bottom of the opening 12, and enters into the opening 12 only partway. In this embodiment, the second mask 13 entered only about 150 nm from the top into the opening 12 having a diameter of 90 nm and a depth of 200 nm.

Baking was then performed to heat the wafer at 150° C. for 90 seconds using the heat plate 14. Thereby, acid is produced in the first mask 11, diffusion of the acid is facilitated, and portions of the second mask 13 contacting the first mask 11 are crosslinked. The crosslinked portions 13a are formed only on the portions of the second mask 13 that enter into the openings 12 as illustrated in FIG. 4D.

After returning the wafer to room temperature by cooling on a cooling plate for 60 seconds, developer was discharged onto the wafer surface for 60 seconds. Thereby, as illustrated in FIG. 4D, only the crosslinked portion 13a which is insoluble to the developer remains. Otherwise, the second mask 13 is removed from the first mask 11.

By leaving the crosslinked portion 13a on the side face inside the opening 12, an opening 12 having a diameter smaller than a diameter of the opening 12 made by only patterning the first mask 11 can be obtained. By etching the film to be fashioned 10 using such a mask, it is possible to form a finer pattern. For a hole pattern having an opening 12 diameter of 90 nm when formed by patterning the first mask 11, the opening diameter of the portion formed by the crosslinked portion 13a on the side face was able to be reduced to 70 nm.

Furthermore, hydrophobizing treatment is performed on the interior face of the opening 12 of the first mask 11 in this embodiment. The second mask 13 is thereby prevented from reaching the bottom of the opening 12 during the coating, and the crosslinked portion 13a can be formed only on the side face inside the opening 12.

Accordingly, crosslinked portions 13a can be prevented from connecting along the bottom face of the opening or having a small spacing therebetween. Thereby, unopened defects of the film to be fashioned 10 and transfer defects of the mask pattern can be prevented.

As described above, fluorination can be performed to provide a highly hydrophobic first mask 11 having a contact angle greater than 70 degrees in the case where the first mask 11 is formed by a material which can undergo direct fluorination. In the case where the first mask 11 is formed by a material which includes, for example, a silanol group and cannot undergo direct fluorination, fluorination can be performed after treatment to modify with an alkylsilyl group similarly to the first and second embodiments described above. Thereby, a highly hydrophobic first mask 11 having a contact angle greater than 70 degrees can be provided. Alternatively, in the case where treatment to modify with the alkylsilyl group provides a first mask 11 sufficiently hydrophobic to prevent the second mask 13 from reaching the bottom of the opening, the fluorination may be unnecessary.

Hereinabove, embodiments of the present invention are described with reference to specific examples. However, the present invention is not limited thereto, and various modifications are possible based on the technical spirit of the present invention. Each of the materials, dimensions, treatment conditions, and the like illustrated in the embodiments described above is one example, and may be appropriately modified to the extent that the purport of the present invention is included.

1. A method for manufacturing a semiconductor device, comprising:
performing modifying a surface of a semiconductor wafer including a silanol group on the surface with an alkylsilyl group; and
fluorinating an alkyl group of the alkylsilyl group with which the surface was modified.

2. The method according to claim 1, wherein modifying with the alkylsilyl group is performed on a silicon oxide film formed on the surface of the semiconductor wafer.

3. The method according to claim 1, wherein the surface of the semiconductor wafer is modified with the alkylsilyl group by exposing the surface to a vapor of at least one selected from the group consisting of HMDS (Hexamethyldisilazane), TMSDEA (Trimethylsilyldiethylamine), DMSDEA (Dimethylsilyldiethylamine), TMSDMA (Trimethylsilyldimethylamine), and DMSDMA (Dimethylsilyldimethylamine).

4. The method according to claim 1, further comprising forming a hydrophobic film on the surface after the fluorinating.

5. The method according to claim 4, wherein the forming a hydrophobic film includes supplying a hydrophobic material to the surface of the semiconductor wafer in a liquid state.

6. The method according to claim 4, wherein the hydrophobic film includes a protective film for immersion exposure.

7. A method for manufacturing a semiconductor device comprising
performing hydrophobizing on an exposed hydrophilic first surface of a semiconductor wafer including, on the same major surface side, the first surface and a hydrophobic second surface patterned on the first surface to expose a portion of the first surface.

8. The method according to claim 7, wherein
the first surface includes a silanol group and the second surface does not include a silanol group, and
the hydrophobizing includes performing modifying the first surface with an alkylsilyl group and fluorinating an alkyl group of the alkylsilyl group with which the first surface was modified.

9. The method according to claim 8, wherein
the first surface is a surface of a silicon oxide film and the second surface is a surface of a silicon nitride film.

10. The method according to claim 8, wherein the first surface is modified with the alkylsilyl group by exposing the first surface to a vapor of at least one selected from the group consisting of HMDS (Hexamethyldisilazane), TMSDEA (Trimethylsilyldiethylamine), DMSDEA (Dimethylsilyldiethylamine), TMSDMA (Trimethylsilyldimethylamine), and DMSDMA (Dimethylsilyldimethylamine).

11. The method according to claim 10, wherein
the second surface also is exposed to the vapor when the first surface is exposed to the vapor, and
the second surface which does not include the silanol group is not modified with the alkylsilyl group.

12. The method according to claim 8, wherein
the first surface upon which the modifying with the alkylsilyl group is performed includes hydrocarbon, and
the first surface is made hydrophobic by directly fluorinating the first surface to fluorinate the hydrocarbon of the first surface.

13. The method according to claim 7, further comprising supplying a hydrophobic material including fluidic properties onto the first surface and the second surface after making the first surface hydrophobic.

14. The method according to claim 13, wherein the hydrophobic material including fluidic properties is a material of a protective film for immersion exposure.

15. A method for manufacturing a semiconductor device, comprising:
forming a first mask which can supply an acid and includes an opening pattern on a semiconductor substrate;
performing hydrophobizing on an exposed surface of the first mask;
forming a second mask which is crosslinkable by acid on the first mask in a way that causes the second mask to enter partway into the opening;
causing a crosslinking reaction of a portion of the second mask contacting the first mask by supplying acid from the first mask to the second mask by baking; and
performing developing to remove a portion of the second mask that is not crosslinked.

16. The method according to claim 15, wherein the first mask is a resist that produces acid when heated.

17. The method according to claim 15, wherein
the first mask includes an organic film, and
the exposed surface of the first mask is made hydrophobic by fluorination.

18. The method according to claim 15, wherein
the exposed surface of the first mask includes a silanol group, and
the performing hydrophobizing on the exposed surface includes modifying the exposed surface with an alkylsilyl group.

19. The method according to claim 18, wherein the performing hydrophobizing on the exposed surface further includes fluorinating an alkyl group of the alkylsilyl group with which the exposed surface was modified.

20. The method according to claim 15, wherein the second mask crosslinked by the acid remains in the opening only on a side face of the portion to which the second mask entered partway.
